(19) United States
(12) Patent Application Publication
(10) Pub. No.: US 2021/0199470 A1
(43) Pub. Date: Jul. 1, 2021

(54) MAGNETIC DETECTION UNIT, ANGLE DETECTION DEVICE, POSITION DETECTION DEVICE, MOTOR CONTROL DEVICE, MOTOR UNIT, AND MOTOR CONTROL METHOD

(71) Applicant: MINEBEA MITSUMI Inc., Nagano (JP)

(72) Inventors: Tomoyuki KITAGAWA, Fukuroi-shi, Shizuoka (JP); Shigeki MIYAJI, Hamamatsu-shi, Shizuoka (JP)

(21) Appl. No.: 17/058,784

(22) PCT Filed: Apr. 10, 2019
(86) PCT No.: PCT/JP2019/015567

§ 371 Date: Nov. 25, 2020

(30) Foreign Application Priority Data
Jun. 1, 2018 (JP) 2018-105856
Jun. 1, 2018 (JP) 2018-105857

(51) Int. Cl. G01D 5/14; H02K 11/215; G01R 15/20

(52) U.S. Cl. CPC G01D 5/145; G01R 15/202; H02K 11/215

(57) ABSTRACT

A novel technology for detecting an absolute position of a target object by using Hall elements is provided.

A magnetic detection unit (2) includes two Hall elements (a first Hall element H1 and a second Hall element H2). The Hall elements are connected in series to each other on an input side of each of the Hall elements.

### TECHNICAL FIELD

The present invention relates to a magnetic detection unit, an angle detection device, a position detection device, a motor control device, a motor unit, and a motor control method, and relates, for example, to an angle detection device configured to detect a moving angle of a rotor of a motor, a motor control device that controls the motor on the basis of the moving angle detected by the angle detection device, a position detection device configured to detect a position of an output shaft of a linear motor, and a motor control device that controls the motor on the basis of position information detected by the position detection device.

### BACKGROUND ART

In a general stepping motor, it is easy to detect a relative rotation angle (moving angle) of a rotor, but it is on the other hand not easy to detect an absolute rotation angle of the rotor such as, for example, a rotation angle in an initial state before the motor is to be operated.

Up to now, as a method for detecting the absolute rotation angle of the stepping motor, a technique for performing an angle detection by attaching an absolute type angle sensor to an output shaft of the stepping motor has been known. For example, Patent Literature 1 discloses a motor control device including an absolute type encoder configured to detect a position of the rotor of the stepping motor.

In addition, in general, to detect an absolute position of the output shaft in a linear motion type motor such as a linear motor in which an output shaft linearly moves, it is necessary to attach a sensor for position detection separately. For example, Patent Literature 2 discloses a linear actuator including an optical system encoder as a position detector that detects a position of the output shaft of the linear motion type motor.

### DOCUMENT LIST

### Patent Literature(s)

Patent Literature 1: Japanese Patent Application Publication No. 2007-252141
Patent Literature 2: Japanese Patent Application Publication No. 2012-173168

### SUMMARY OF INVENTION

### Technical Problem

As a sensor system of an angle sensor of an absolute type, mainly, an optical system and a magnetic system are known. In addition, as a sensor system of a position detector that detects a position of an output shaft of a linear motion type motor, the optical system and the magnetic system described above are known. In general, a problem exists that a price of an angle sensor of an optical system (optical system encoder) is extremely high.

In view of the above, the inventors of the present application have considered an adoption of an angle sensor that is cheaper than the angle sensor of the optical system, that is, an angle sensor using Hall elements as the absolute type angle sensor to be mounted to a stepping motor or the position detector to be mounted to a linear motor.

However, various problems exist even in a case where the Hall elements is adopted as the angle sensor. For example, the Hall element has a problem that a voltage of an output signal of the Hall element is not stable since an internal resistance of the Hall element changes depending on a temperature (for example, 100Ω to 2000Ω). In addition, the Hall element also has a problem that an applicable maximum input current or maximum input voltage is low. For example, only up to 10 mA can be applied to a certain Hall element in a range from −40° C. to 120° C. Furthermore, the Hall element also has a problem that a width of the output voltage (output voltage width) is minute. For example, in a case where a magnetic flux at ±40 mT is detected, the output voltage width of the Hall element is ±0.24 V.

To solve the above-described problems of the Hall elements, a product obtained by combining the Hall elements with a highly precise operational amplifier IC that amplifies the output signals of the Hall elements is commercially available. However, such a product is extremely expensive, and also has a problem that power consumption is high.

The present invention has been made in view of the above-described problems, and it is an object to provide a new technology for detecting an absolute position of a target object by using Hall elements.

### Solution to Problem

A magnetic detection unit according to a representative embodiment of the present invention is characterized by including a plurality of Hall elements, the plurality of Hall elements being connected in series to each other on an input side of each of the Hall elements.

### Effects of Invention

With the angle detection device according to the present invention, it is possible to provide the new technology for detecting the absolute position of the target object by using the Hall elements.

### BRIEF DESCRIPTION OF DRAWINGS

FIG. 1 A diagram illustrating a configuration of a motor unit according to a first embodiment.

FIG. 2 A diagram illustrating a circuit configuration of an angle detection device according to the first embodiment.

FIG. 3A A view illustrating an arrangement example of two Hall elements H1 and H2 according to the first embodiment.

FIG. 3B A view illustrating the arrangement example of the two Hall elements H1 and H2 according to the first embodiment.

FIG. 4 A flowchart illustrating a flow of a motor control method in a motor unit according to the first embodiment.

FIG. 5A A diagram illustrating simulation results of an input signal and an output signal of an amplification circuit on a side of the first Hall element H1 according to the first embodiment.

FIG. 5B A diagram illustrating simulation results of an input signal and an output signal of an amplification circuit on a side of the second Hall element H2 according to the first embodiment.

FIG. 6 A diagram illustrating a configuration of a motor unit according to a second embodiment.

FIG. 7 A diagram illustrating a circuit configuration of a position detection device according to the second embodiment.

FIG. 8A A view illustrating an arrangement example of the two Hall elements H1 and H2 according to the second embodiment.

FIG. 8B A view illustrating an arrangement example of the two Hall elements H1 and H2 according to the second embodiment.

FIG. 9 A flowchart illustrating a flow of a motor control method in a motor unit according to the second embodiment.

FIG. 10 A diagram illustrating simulation results of an input signal and an output signal of an amplification circuit according to the second embodiment.

FIG. 11 A diagram illustrating a circuit configuration of a position detection device according to another embodiment.

### DESCRIPTION OF EMBODIMENTS

### 1. Outline of Embodiments

First, an outline with regard to representative embodiments of the invention disclosed in the present application will be described. It is noted that in the following description, as one example, reference symbols on the drawings corresponding to components of the invention are described in parentheses.

[1] A magnetic detection unit (2) according to a representative embodiment of the present invention includes a plurality of Hall elements (H1, H2), and is characterized in that the plurality of Hall elements are connected in series to each other on an input side of each of the Hall elements.

[2] In the magnetic detection unit according to the above-described [1], the plurality of Hall elements may include a first Hall element (H1) having a first positive side input terminal (IP1), a first negative side input terminal (IN1), a first positive side output terminal (OP1), and a first negative side output terminal (ON1), and a second Hall element (H2) having a second positive side input terminal (IP2), a second negative side input terminal (IN2), a second positive side output terminal (OP2), and a second negative side output terminal (ON2), a power supply voltage (VDD) may be applied to the first positive side input terminal of the first Hall element, the first negative side input terminal of the first Hall element may be connected to the second positive side input terminal of the second Hall element, and a ground voltage (GND) may be applied to the second negative side input terminal of the second Hall element.

[3] An angle detection device (1) according to a representative embodiment of the present invention is characterized by including the magnetic detection unit (2) according to the above-described [2], and a plurality of amplification circuits (31, 32) respectively disposed for the Hall elements and configured to amplify output signals (401, 402, 411, 412) of the corresponding Hall elements.

[4] In the angle detection device according to the above-described [3], the plurality of amplification circuits may include a first amplification circuit (31) that amplifies a difference between a voltage of the first positive side output terminal and a voltage of the first negative side output terminal in the first Hall element, and a second amplification circuit (32) that amplifies a difference between a voltage of the second positive side output terminal and a voltage of the second negative side output terminal in the second Hall element, the first amplification circuit may have a differential input circuit (313) including a P type transistor pair (Q11, Q12), and the second amplification circuit may have a differential input circuit (323) including an N type transistor pair (Q21, Q22).

[5] A motor control device according to a representative embodiment of the present invention is characterized by including the angle detection device (1) according to the above-described [3] or [4], and a control device (4) that generates a drive control signal (8) for controlling drive of a motor on the basis of the signals (401A, 402A, 411A, 412A) respectively amplified by the plurality of amplification circuits.

[6] A motor unit (100) according to a representative embodiment of the present invention is characterized by including the motor control device (10) according to the above-described [5], the motor (20) to be controlled on the basis of the drive control signal generated by the control device, and a magnet (22) disposed on an output shaft (21) of the motor, the plurality of Hall elements being arranged while being separated from each other along a direction (R) in which the magnet rotates.

[7] In the motor unit according to the above-described [6], the Hall elements may include two Hall elements, and the two Hall elements may be arranged such that phases are mutually shifted by 90 degrees along the direction in which the magnet rotates.

[8] A position detection device (1A/1B) according to a representative embodiment of the present invention includes the magnetic detection unit (2) according to the above-described [2], and an amplification circuit (3A/3B) that amplifies output signals (411, 412/401, 402) of one Hall element (H2/H1) of the plurality of Hall elements, the position detection device being characterized in that the plurality of Hall elements are connected in series to each other on an input side of each of the Hall elements.

[9] In the position detection device according to the above-described [8], the amplification circuit may amplify a difference between a voltage of the second positive side output terminal and a voltage of the second negative side output terminal in the second Hall element, and the amplification circuit may have a differential input circuit (323) including an N type transistor pair (Q21, Q22).

[10] Another motor control device (10A) according to a representative embodiment of the present invention is characterized by including the position detection device (1A) according to the above-described [8] or [9], and a control device (4A) that generates a drive control signal (8A) for controlling drive of the motor (20A) on the basis of the signals amplified by the amplification circuit.

[11] Another motor unit (100A) according to a representative embodiment of the present invention may include the motor control device (10A) according to the above-described [10], the motor, and a magnet (22A), the motor may be a linear motion type motor that has an output shaft (21A) in which a movement in an axis line (Q) direction of the output shaft is controlled on the basis of the drive control signal, one of the one Hall element and the magnet may be fixed to the output shaft, and the other one of the one Hall element and the magnet may be fixed to a position facing the output shaft.

[12] In the motor unit according to the above-described [11], the one Hall element may be fixed to the output shaft, and the magnet may be fixed to a position facing the output shaft.

[13] A method according to a representative embodiment of the present invention is a motor control method using a motor control device (10) that includes a plurality of Hall elements (H1, H2) configured to detect a magnetic flux of a magnet that rotates in accordance with rotation of a rotor of a motor, a plurality of amplification circuits (31, 32) respectively disposed for the Hall elements, and a control device (4) that generates a drive control signal (8) for controlling drive of the motor (20), the plurality of Hall elements being connected in series to each other on respective input sides, the method being characterized by including a step (S2) of generating the output signals in accordance with the magnetic flux detected by the Hall elements, a step (S3) of respectively amplifying the output signals generated by the corresponding Hall elements by the plurality of amplification circuits, and a step of (S4) calculating a rotation angle of the rotor by the control device on the basis of the signals amplified by each of the amplification circuits, and generating and supplying a drive control signal to the motor on the basis of the calculated rotation angle.

[14] A method according to a representative embodiment of the present invention is a motor control method using a motor control device (10A) that has a magnetic detection unit (2) having a plurality of Hall elements (H1, H2) connected in series to each other on respective input sides, an amplification circuit (3A), a magnet (22A), and a control device (4A) that generates a drive control signal (8A) for controlling drive of a linear motion type motor (20A) in which an output shaft (21A) can move in an axis direction (P) of the output shaft, one of the plurality of Hall elements and the magnet being disposed in a position that moves in accordance with movement of the output shaft, the other one of the plurality of Hall elements and the magnet being disposed in a position facing the output shaft, the method being characterized by including a step (S2A) of generating signals (411, 412) on the basis of a magnetic flux detected by one of the plurality of Hall elements, a step (S3A) of amplifying the signals (411, 412) generated by the one Hall element (H2) by the amplification circuit, and a step (S4A) of calculating a position of the output shaft by the control device on the basis of the signals amplified by the amplification circuit, and generating and supplying the drive control signal on the basis of the calculated position to the linear motion type motor.

### 2. Specific Examples of Embodiments

Hereinafter, specific examples of embodiments of the present invention will be described with reference to the drawings. It is noted that in the following description, common components according to the respective embodiments are assigned with the same reference symbols, and the redundant description will be omitted. In addition, the drawings are schematic drawings, and it is to be noted that a dimensional relationship between the respective components, a ratio of the respective components, and the like may be different from the actuality in some cases. Between the mutual drawings too, parts in which a dimensional relationship and ratio are mutually different may be included in some cases.

### First Embodiment

### <Motor Unit>

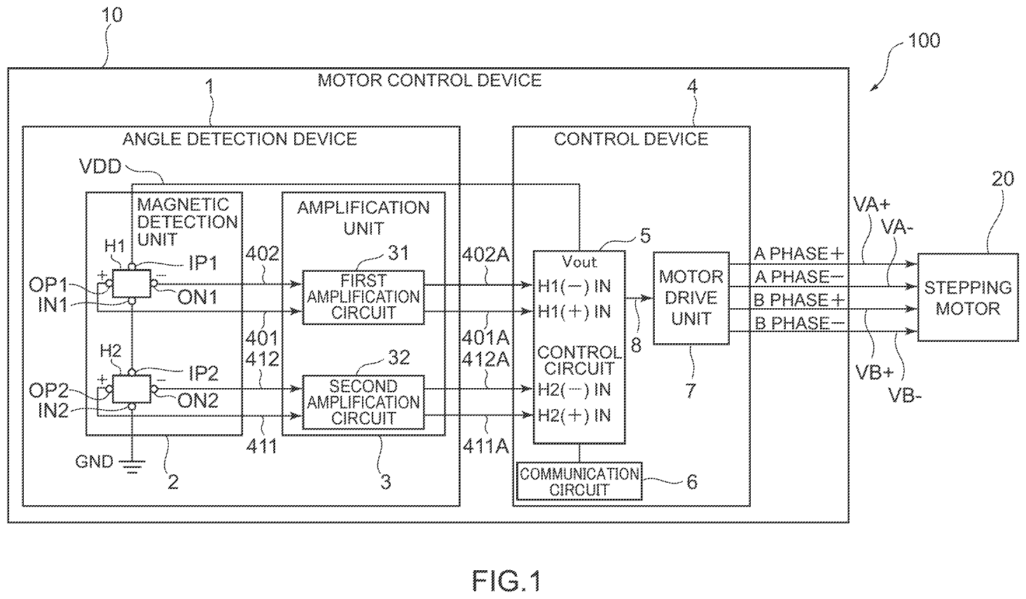

FIG. 1 is a diagram illustrating a configuration of a motor unit according to a first embodiment.

As illustrated in FIG. 1, a motor unit 100 has a motor 20 and a motor control device 10.

The motor 20 is, for example, a stepping motor. According to the present embodiment, the description will be provided by taking a case as an example where the motor 20 is a two-phase stepping motor including two phases of a phase A and a phase B.

The motor control device 10 is configured to supply drive power to the motor 20 and drive the motor 20. Specifically, the motor control device 10 has an angle detection device 1 and a control device 4. The angle detection device 1 is an device that generates and outputs a signal corresponding to a rotational position of the rotor in accordance with rotation of a rotor of the motor 20. The control device 4 applies a drive signal to the motor 20 to rotate the motor 20 on the basis of the signal output from the angle detection device 1 in accordance with the rotation of the rotor of the motor 20.

### <Control Device>

The control device 4 has a motor drive unit 7 that drives the motor 20, a control circuit 5 that controls drive of the motor 20, and a communication circuit 6 configured to communicate with an external device (not illustrated). It is noted that components of the control device 4 illustrated in FIG. 1 are a part of the entirety, and the control device 4 may also have other components in addition to the components illustrated in FIG. 1.

The motor drive unit 7 generates drive signals (drive voltages) VA+, VA−, VB+, and VB− for driving coils of respective phases forming the motor 20 on the basis of a drive control signal 8 output from the control circuit 5, and supplies the drive signals to the respective phases of the motor 20.

The control circuit 5 is formed, for example, by a program processing device such as an MCU (Microprogram Control Unit) or a DSP (Digital Signal Processor). It is noted that the entirety of the control circuit 5 may also be packaged as one integrated circuit device, or the entirety or a part of the control circuit 5 may also be packaged together with other devices to form one integrated circuit device.

The control circuit 5 generates the drive control signal 8 on the basis of a command rotation angle signal (signal in accordance with a target rotation angle) set from the external device (user) via the communication circuit 6 or the like, and signals 401A, 402A, 411A, and 412A indicating rotation angles of the motor 20 to be output from the angle detection device 1 which will be described below, and supplies the generated drive control signal 8 to the motor drive unit 7. That is, the control circuit 5 generates the drive control signal 8 for driving the motor 20 while a feedback is applied based on the comparison between the target rotation angle and an actual measurement value of the rotation angle of the motor 20, and supplies the drive control signal 8 to the motor drive unit 7 to perform the rotation control of the motor 20.

In addition, the control circuit 5 has a function of outputting a fixed voltage that can be used as a power supply voltage of a peripheral circuit. The control circuit 5 is supplied with the power supply voltage at 3.3 V, for example, to operate, and also outputs a fixed voltage at 3.3 V, for example, while the input power supply voltage is set as a power supply voltage VDD of the angle detection device 1.

### <Angle Detection Device>

The angle detection device 1 has a configuration in which a plurality of Hall elements serving as magnetic detection elements are connected in series to each other on an input side of each of the Hall elements. The angle detection device 1 is an absolute type angle sensor that can detect an absolute rotation angle of the rotor of the motor 20 on the basis of detection signals of the plurality of Hall elements.

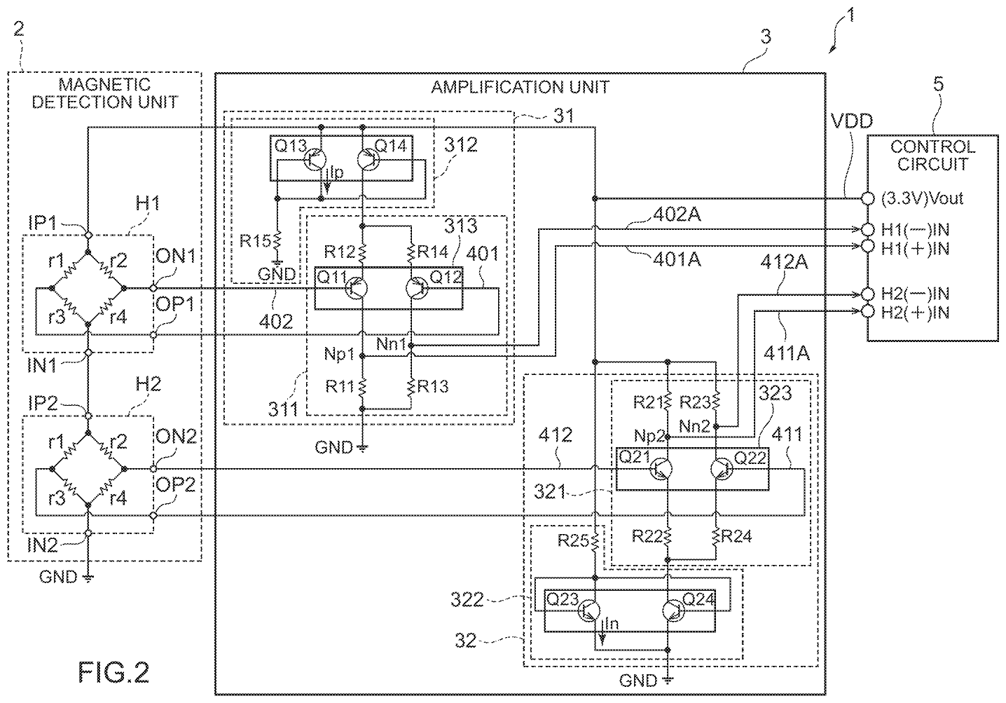

FIG. 2 is a diagram illustrating a circuit configuration of the angle detection device 1 according to the first embodiment.

As illustrated in FIG. 2, the angle detection device 1 has the magnetic detection unit 2 and an amplification unit 3.

### (1) Magnetic Detection Unit

The magnetic detection unit 2 has a plurality of Hall elements configured to detect a position of the rotor of the motor 20. According to the present embodiment, as one example, descriptions will be provided while the magnetic detection unit 2 has two Hall elements H1 and H2, in which the first Hall element H1 and the second Hall element H2 have the same characteristics.

Each of the Hall elements H1 and H2 can be equivalently represented by a bridge circuit formed by four internal resistances r1 to r4 as illustrated in FIG. 2. In the first Hall element H1, four nodes to which the respective internal resistances r1 to r4 are mutually connected are respectively a first positive side input terminal IP1, a first negative side input terminal IN1, a first positive side output terminal OP1, and a first negative side output terminal ON1. Similarly, in the second Hall element H2, four nodes to which the respective internal resistances r1 to r4 are mutually connected are respectively a second positive side input terminal IP2, a second negative side input terminal IN2, a second positive side output terminal OP2, and a second negative side output terminal ON2.

In the magnetic detection unit 2, the plurality of Hall elements are connected in series to each other on the input side of each of the Hall elements. Specifically, the first Hall element H1 and the second Hall element H2 are connected in series to each other on the respective input sides between the power supply voltage VDD and a ground voltage GND.

More specifically, as illustrated in FIG. 2, the first positive side input terminal IP1 of the first Hall element H1 is applied with the power supply voltage VDD. The first negative side input terminal IN1 of the first Hall element H1 is connected to the second positive side input terminal IP2 of the second Hall element H2. The second negative side input terminal IN2 of the second Hall element H2 is applied with the ground voltage GND.

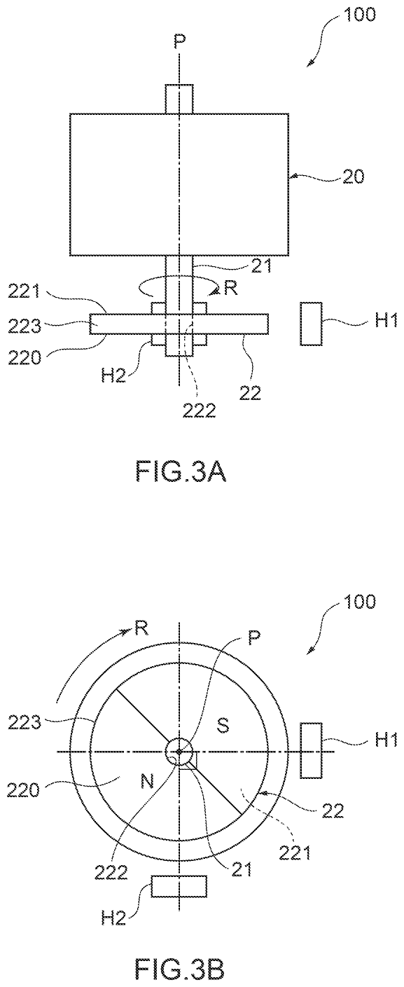

FIG. 3A and FIG. 3B are views illustrating arrangement examples of the two Hall elements H1 and H2 according to the first embodiment.

FIG. 3A illustrates the arrangement example of the two Hall elements H1 and H2 viewed from a direction perpendicular to an axis line P of an output shaft 21 of the motor 20 in the motor unit 100. FIG. 3B illustrates the arrangement example of the two Hall elements H1 and H2 viewed from an axis line direction of the output shaft 21 of the motor 20 in the motor unit 100.

As illustrated in FIGS. 3A and 3B, in the motor unit 100, a sensor magnet (magnet) 22 is disposed on the output shaft 21 coupled to the rotor of the motor 20 (not illustrated) 1. The sensor magnet 22 is, for example, a disk-like bipolar permanent magnet.

The sensor magnet 22 has, for example, a main surface 220 and a rear surface 221 that is back to back to the main surface 220 as in the present embodiment. Furthermore, the sensor magnet 22 has a through-hole 222 penetrating through the main surface 220 and the rear surface 221. The sensor magnet 22 is fixed to the output shaft 21 in a state where the output shaft 21 penetrates through the through-hole 222. The sensor magnet 22 rotates in a direction of reference symbol R by a rotation of the rotor of the motor 20 (output shaft 21), for example.

The two Hall elements H1 and H2 are disposed in positions in the vicinity of the sensor magnet 22 where it is possible to precisely detect a magnetic flux of the sensor magnet 22. Specifically, as illustrated in FIGS. 3A and 3B, the two Hall elements H1 and H2 are arranged while being separated from each other along the direction (rotation direction of the output shaft 21) R in which the sensor magnet 22 rotates. For example, the two Hall elements H1 and H2 face a side surface 223 of the sensor magnet 22, and are respectively disposed in positions phases are shifted by 90 degrees in the direction R in which the sensor magnet 22 rotates.

The two Hall elements H1 and H2 detect the magnetic flux of the sensor magnet 22 based on the rotation of the output shaft 21 of the motor 20, and output analog signals as output signals where voltages change in accordance with the change of the magnetic flux (hereinafter, also referred to as “Hall signals”.).

For example, when the output shaft 21 rotates at a certain speed, the first Hall element H1 outputs a sinusoidal Hall signal 401 from a first positive side output terminal OP1, and also outputs a sinusoidal Hall signal 402 having a polarity different from that of the Hall signal 401 from a first negative side output terminal ON1. Similarly, the second Hall element H2 outputs a sinusoidal Hall signal 411 from a second positive side output terminal OP2, and also outputs a sinusoidal Hall signal 412 having a polarity different from that of the Hall signal 411 from a second negative side output terminal ON2.

As illustrated in FIGS. 3A and 3B, by arranging the first Hall element H1 and the second Hall element H2 such that the phases are mutually shifted by 90 degrees in the direction R in which the sensor magnet 22 rotates, a signal pair (Hall signals 401 and 402) output from the first Hall element H1 and a signal pair (Hall signals 411 and 412) output from the second Hall element H2 have a relationship in which the phases are shifted by 90 degrees. When the Hall signals 401, 402 and the Hall signals 411, 412 in which the phases are mutually different are used, the control circuit 5 can calculate the absolute rotation angle of the rotor of the motor 20.

### (2) Amplification Unit

As illustrated in FIG. 2, the amplification unit 3 is a functional unit that amplifies and outputs the respective Hall signals output from the two Hall elements H1 and H2. The amplification unit 3 is disposed for each set of the two Hall elements H1 and H2, and has a first amplification circuit 31 and a second amplification circuit 32 that amplify the Hall signals output from the corresponding Hall elements H1 and H2.

The first amplification circuit 31 is a circuit that amplifies each of the Hall signals 401 and 402 of the first Hall element H1. Specifically, the first amplification circuit 31 has a constant current source circuit 312 and a differential amplification circuit 311.

The constant current source circuit 312 is a circuit that generates and supplies a constant current to the differential amplification circuit 311. The constant current source circuit 312 includes, for example, P type transistors Q13 and Q14 and a resistance R15.

Herein, the P type transistor refers to a transistor of a predetermined conductivity type such as, for example, a PNP junction bipolar transistor or a P channel type field effect transistor (for example, a P channel type MOS transistor).

For example, the P type transistors Q13 and Q14 are PNP type bipolar transistors. The transistor Q13 and the transistor Q14 form a current mirror circuit.

In the constant current source circuit 312, a base electrode and a collector electrode of the transistor Q13 are commonly connected, and the power supply voltage VDD is supplied to an emitter electrode of the transistor Q13. Herein, the power supply voltage VDD is the voltage output from the control circuit 5 as described above.

One end of the resistance R15 is connected to the base electrode and the collector electrode of the transistor Q13, and another end of the resistance R15 is supplied with the ground voltage GND. An emitter electrode of the transistor Q14 is supplied with the power supply voltage VDD. A base electrode of the transistor Q14 is connected to the one end of the resistance R15 together with the base electrode and the collector electrode of the transistor Q13, and a collector electrode of the transistor Q14 is connected to a node to which a resistance R12 and a resistance R14 forming a differential input circuit 313 which will be described below are mutually connected.

In accordance with the constant current source circuit 312 having the above-described configuration, when a base-emitter voltage of the transistor Q13 is set as VBE13, a current Ip at Ip=(VDD−VBE13)/R15 is output from the transistor Q13, and a current that has copied the current Ip is supplied from the transistor Q14 to the differential amplification circuit 311.

The differential amplification circuit 311 is a circuit that amplifies a difference between the Hall signal 401 output from the first positive side output terminal OP1 of the first Hall element H1 and the Hall signal 402 output from the first negative side output terminal ON1 of the first Hall element H1.

The differential amplification circuit 311 includes the differential input circuit 313 and resistances R11 to R14.

The differential input circuit 313 includes, for example, a P type (first conductivity type) transistor pair. For example, the differential input circuit 313 has PNP junction transistors (bipolar transistors) Q11 and Q12 as the transistor pair formed such that the characteristics are equal to each other.

A base electrode of the transistor Q11 is connected to the first negative side output terminal ON1 of the first Hall element H1, and a base electrode of the transistor Q12 is connected to the first positive side output terminal OP1 of the first Hall element H1.

One end of the resistance R11 is connected to a collector electrode of the transistor Q11, and another end of the resistance R11 is supplied with the ground voltage GND. One end of the resistance R13 is connected to a collector electrode of the transistor Q12, and another end of the resistance R13 is supplied with the ground voltage GND.

One end of the resistance R12 is connected to an emitter electrode of the transistor Q11. One end of the resistance R14 is connected to an emitter electrode of the transistor Q12. Another end of the resistance R12 is connected to another end of the resistance R14 and the collector electrode of the transistor Q14.

In accordance with the differential amplification circuit 311 having the above-described configuration, an amplification signal 401A having a positive polarity which is obtained by amplifying the difference between the Hall signal 401 and the Hall signal 402 is output from a node Np1 to which the one end of the resistance R11 and the collector electrode of the transistor Q11 are connected. In addition, an amplification signal 402A having a negative polarity which is obtained by amplifying the difference between the Hall signal 401 and the Hall signal 402 is output from a node Nn1 to which the one end of the resistance R13 and the collector electrode of the transistor Q12 are connected.

The second amplification circuit 32 is a circuit that amplifies each of the Hall signals 411 and 412 of the second Hall element H2. Specifically, the second amplification circuit 32 has a constant current source circuit 322 and a differential amplification circuit 321.

The constant current source circuit 322 is a circuit that generates and supplies a constant current to the differential amplification circuit 321. The constant current source circuit 322 includes, for example, N type transistors Q23 and Q24 and a resistance R25.

Herein, the N type transistor refers to a transistor having a conductivity type opposite to the P type transistor such as, for example, an NPN junction bipolar transistor or an N channel type field effect transistor (for example, an N channel type MOS transistor).

For example, the N type transistors Q23 and Q24 are NPN type bipolar transistors. The transistor Q23 and the transistor Q24 form a current mirror circuit.

In the constant current source circuit 322, a base electrode and a collector electrode of the transistor Q23 are commonly connected, and an emitter electrode of the transistor Q23 is supplied with the ground voltage GND.

One end of the resistance R25 is connected to the base electrode and the collector electrode of the transistor Q23, and another end of the resistance R25 is supplied with the power supply voltage VDD. An emitter electrode of the transistor Q24 is supplied with the ground voltage GND. A base electrode of the transistor Q24 is connected to the one end of the resistance R25 together with the base electrode and the collector electrode of the transistor Q23, and a collector electrode of the transistor Q24 is connected to a node to which a resistance R22 and a resistance R24 forming a differential input circuit 323 which will be described below are mutually connected.

In accordance with the constant current source circuit 322 having the above-described configuration, when a base-emitter voltage of the transistor Q23 is set as VBE23, a current In=(VDD−VBE23)/R25 is output from the transistor Q23, and a current that has copied the current In is supplied from the transistor Q24 to the differential amplification circuit 321.

The differential amplification circuit 321 is a circuit that amplifies and outputs a difference between the Hall signal 411 output from the second positive side output terminal OP2 of the second Hall element H2 and the Hall signal 412 output from the second negative side output terminal ON2 of the second Hall element H2.

The differential amplification circuit 321 includes the differential input circuit 323 and resistances R21 to R24. The differential input circuit 323 includes, for example, an N type (second conductivity type) transistor pair. For example, the differential input circuit 323 has NPN junction bipolar transistors Q21 and Q22 as a transistor pair formed such that the characteristics are equal to each other.

A base electrode of the transistor Q21 is connected to the second negative side output terminal ON2 of the second Hall element H2, and a base electrode of the transistor Q22 is connected to the second positive side output terminal OP2 of the second Hall element H2.

One end of the resistance R21 is connected to a collector electrode of the transistor Q21, and another end of the resistance R21 is supplied with the power supply voltage VDD. One end of the resistance R23 is connected to a collector electrode of the transistor Q22, and another end of the resistance R23 is supplied with the power supply voltage VDD. One end of the resistance R22 is connected to an emitter electrode of the transistor Q21. One end of the resistance R24 is connected to an emitter electrode of the transistor Q22. Another end of the resistance R22 is connected to another end of the resistance R24 and a collector electrode of the transistor Q24.

In accordance with the differential amplification circuit 321 having the above-described configuration, an amplification signal 411A having the positive polarity which is obtained by amplifying the difference between the Hall signal 411 and the Hall signal 412 is output from the node Np2 to which the one end of the resistance R21 and the collector electrode of the transistor Q21 are connected. In addition, an amplification signal 412A having a negative polarity which is obtained by amplifying the difference between the Hall signal 411 and the Hall signal 412 is output from a node Nn2 to which the one end of the resistance R23 and the collector electrode of the transistor Q22 are connected.

In this manner, the Hall signals 401 and 402, and 411 and 412 of the respective Hall elements H1 and H2 are amplified by the amplification unit 3 and input to the control circuit 5 as the amplification signals 401A and 402A, and 411A and 412A.

The control circuit 5 calculates the actual measurement value of the rotation angle of the rotor of the motor 20 on the basis of the input amplification signals 401A, 402A, 411A, and 412A. As described above, the amplification signals 401A, 402A, 411A, and 412A (Hall signals 401, 402, 411, and 412) are signals based on the magnetic flux detected by the two Hall elements H1 and H2 that are arranged in positions mutually different in the rotation direction R of the sensor magnet 22. Therefore, when the two amplification signals 401A and 402A and the two amplification signals 411A and 412A having mutually different phases are used, the control circuit 5 can calculate the absolute rotation angle of the rotor of the motor 20.

It is noted that as a method of calculating the absolute rotation angle of the rotor from the two signals having the mutually different phases, a known calculation method applied to an absolute type rotary encoder or the like can be used. For example, a program related to the calculation method may be stored in a storage unit in the control circuit 5, and the control circuit 5 may calculate the absolute rotation angle of the rotor of the motor 20 on the basis of the program and the amplification signals 401A, 402A, 411A, and 412A.

### <Motor Control Method>

Thereafter, a control method of the motor 20 in the motor unit 100 will be described.

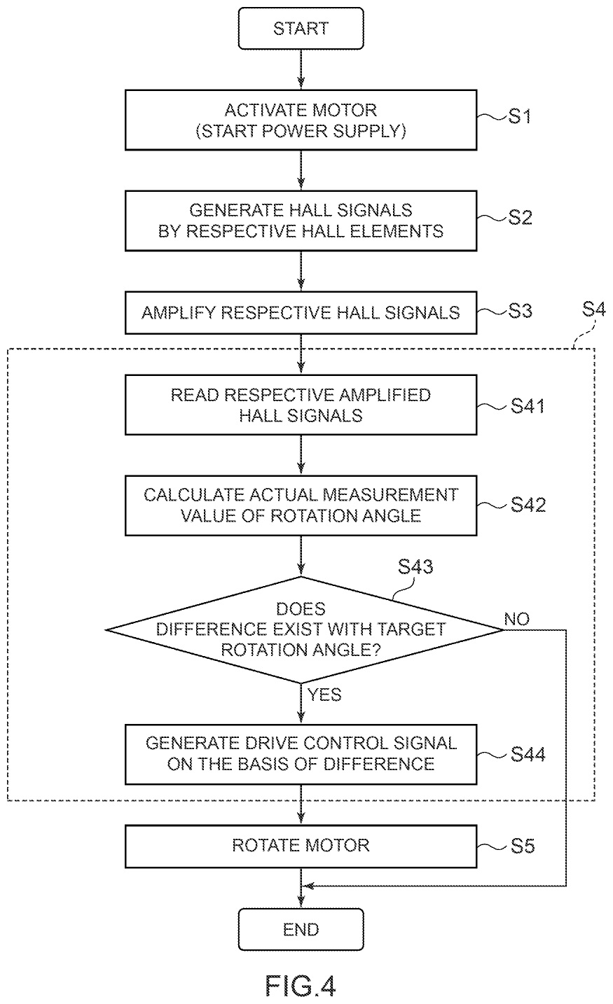

FIG. 4 is a flowchart illustrating a flow of the motor control method in the motor unit 100 according to the first embodiment.

First, when the motor unit 100 is supplied with the power supply voltage, the motor unit 100 is activated (step S1). Thereafter, the Hall elements H1 and H2 forming the magnetic detection unit 2 of the angle detection device 1 respectively detect the magnetic fluxes of the sensor magnet 22 fixed to the output shaft 21 of the motor 20, and generate the Hall signals 401 and 402, and 411 and 412 in accordance with the detected magnetic fluxes (step S2).

Thereafter, the first amplification circuit 31 and the second amplification circuit 32 of the angle detection device 1 respectively amplify the Hall signals 401 and 402, and 411 and 412 output from the respectively corresponding first Hall element H1 and second Hall element H2 and generate the amplification signals 401A and 402A, and 411A and 412A (step S3).

Thereafter, the control device 4 executes processing for generating the drive signals for driving the motor 20 on the basis of the amplification signals 401A, 402A, 411A, and 412A output from the angle detection device 1 (step S4).

Specifically, first, the control circuit 5 of the control device 4 reads the amplification signals 401A, 402A, 411A, and 412A obtained by amplifying the Hall signals of the respective Hall elements H1 and H2 (step S41). For example, the control circuit 5 converts the amplification signals 401A, 402A, 411A, and 412A corresponding to analog signals into digital signals by analog/digital conversion circuit (not illustrated) disposed inside the control circuit 5, and stores the digital signals in the storage unit (not illustrated) disposed inside the control circuit 5.

Thereafter, the control circuit 5 calculates the actual measurement value of the rotation angle of the rotor of the motor 20 on the basis of the read amplification signals 401A, 402A, 411A, and 412A (step S42). At this time, since the first Hall element H1 and the second Hall element H2 are disposed in the positions where the phases are mutually shifted in the rotation direction R of the sensor magnet 22 (for example, positions where the phases are shifted by 90 degrees) as described above, when the amplification signals 401A, 402A, 411A, and 412A based on the Hall signals of the two Hall elements H1 and H2 are used, it is possible to calculate the absolute rotation angle of the rotor.

Thereafter, the control circuit 5 compares the target rotation angle set from the external device via the communication circuit 6 or the like with the actual measurement value of the rotation angle of the rotor of the motor 20 calculated in step S42 (step S43). In step S43, in a case where a difference exists between the target rotation angle and the actual measurement value of the rotation angle, the control circuit 5 generates the drive control signal 8 such that the difference is to be reduced (step S44).

Thereafter, the motor drive unit 7 generates the drive signals (drive voltages) VA+, VA−, VB+, and VB− on the basis of the drive control signal 8 generated in step S44, and supplies the drive signals to the respective phases of the motor 20 to rotate the motor 20 (step S5). Thus, the motor 20 is controlled to realize the target rotation angle.

### <Effects of Angle Detection Device>

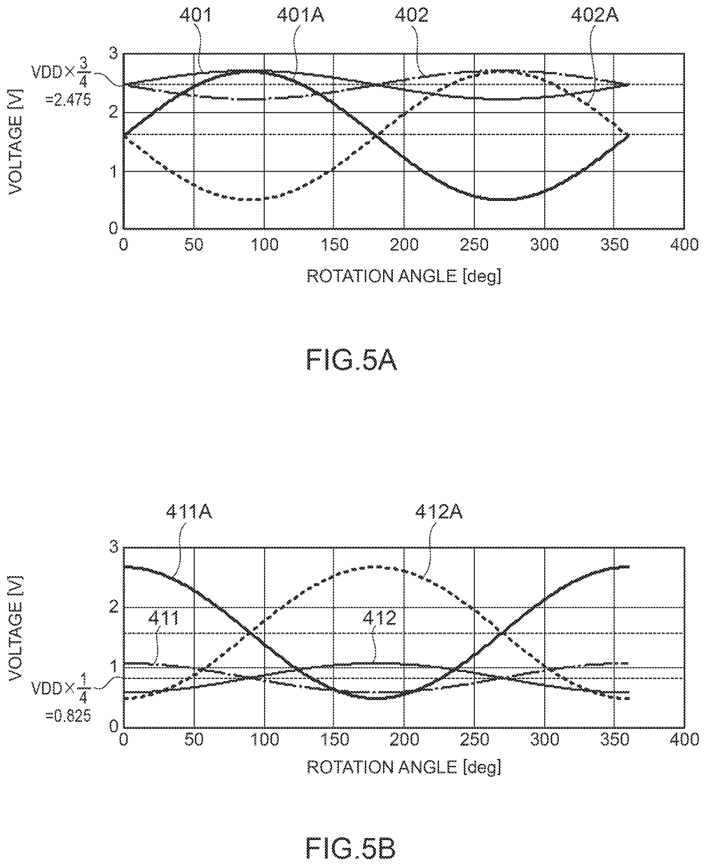

FIG. 5A and FIG. 5B are diagrams illustrating simulation results of input signals and output signals of the first amplification circuit 31 and the second amplification circuit 32 in the angle detection device 1 according to the first embodiment. In this simulation, the power supply voltage VDD=3.3 V and the ground voltage GND=0 V are set.

In FIGS. 5A and 5B, the horizontal axis represents the rotation angle of the rotor [deg], and the vertical axis represents a voltage [V]. In addition, FIG. 5A illustrates the Hall signals 401 and 402 of the first Hall element H1 corresponding to the input signals of the first amplification circuit 31, and the amplification signals 401A and 402A corresponding to the output signals of the first amplification circuit 31. FIG. 5B illustrates the Hall signals 411 and 412 of the second Hall element H2 corresponding to the input signals of the second amplification circuit 32 and the amplification signals 411A and 412A corresponding to the output signals of the second amplification circuit 32.

In general, in the Hall element, when the magnetic flux to be detected is zero, that is, when each of the internal resistances r1 to r4 forming the Hall element (mutually equal resistance values) is in an equilibrium state, the Hall signal of the positive side output and the Hall signal of the negative side output have the same voltages. For this reason, the voltage when the internal resistances r1 to r4 are in the equilibrium state is set as a reference, the Hall signal output from the Hall element is an analog signal in which a voltage changes in a range of ±0.1 V to ±0.5 V using the reference voltage as the center in accordance with the detected magnetic flux, for example.

In the angle detection device 1 according to the first embodiment, as described above, the first Hall element H1 and the second Hall element H2 in the magnetic detection unit 2 are connected in series to each other on the respective input sides between the power supply voltage VDD and the ground voltage GND. For this reason, the reference voltage of the Hall signal is a voltage obtained by dividing the voltage between the power supply voltage VDD and the ground voltage GND on the basis of resistance ratios of the internal resistances r1 to r4 of each of the Hall elements H1 and H2. That is, when the respective internal resistances r1 to r4 of the two Hall elements H1 and H2 are in the equilibrium state, the reference voltage of the Hall signal of the first Hall element H1 is set as “VDD×3/4”, and the reference voltage of the second Hall element H2 is set as “VDD×1/4”.

For example, as illustrated in FIG. 5A, when the power supply voltage VDD=3.3 V and the ground voltage GND=0 V are set, the reference voltage of the first Hall element H1 is set as 2.475 V (=3.3×3/4), and the Hall signals 401 and 402 of the first Hall element H1 have waveforms that change by up to approximately ±0.24 V while 2.475 V is set as the center. Similarly, as illustrated in FIG. 5B, the reference voltage of the second Hall element H2 is set as 0.825 V (=3.3×1/4), and the Hall signals 411 and 412 of the second Hall element H2 have waveforms that change by up to approximately ±0.24 V while 0.825 V is set as the center.

On the other hand, since the first amplification circuit 31 to which the Hall signals 401 and 402 of the first Hall element H1 are input has the differential input circuit 313 formed by the transistors Q11 and Q12 of the PNP type, unless the signal in the appropriate voltage range is input, the first amplification circuit 31 does not perform the appropriate amplification operation. For example, in order that the transistors Q11 and Q12 appropriately operate, when a saturation voltage of a PN junction portion of the transistors Q11 and Q12 is set as VBE10 (≈0.6 V), a voltage equal to or lower than “VDD−VBE10 (≈3.3−0.6=2.7V)” needs to be input to the base electrodes of the transistors Q11 and Q12. On the other hand, in a case where a low voltage close to the ground voltage GND is input to the base electrodes of the transistors Q11 and Q12, the output voltage of the first amplification circuit 31 saturates.

Similarly, since the second amplification circuit 32 to which the Hall signals 411 and 412 of the second Hall element H2 are input has the differential input circuit 323 formed by the transistors Q21 and Q22 of the NPN type, unless the signal in the appropriate voltage range is input, the second amplification circuit 32 does not perform the appropriate amplification operation. For example, in order that the transistors Q21 and Q22 appropriately operate, when a saturation voltage of a PN junction portion of the transistors Q21 and Q22 is set as VBE20 (≈0.6 V), a voltage equal to or higher than “VBE20 (≈0.6 V)” needs to be input to the base electrodes of the transistors Q21 and Q22. On the other hand, in a case where a high voltage close to the power supply voltage VDD is input to the base electrodes of the transistors Q21 and Q22, the output voltage of the second amplification circuit 32 saturates.

In this manner, the first amplification circuit 31 and the second amplification circuit 32 that amplify the output signals from the first Hall element H1 and the second Hall element H2 have a limitation on the input voltage range, but since the angle detection device 1 according to the present embodiment adopts a configuration in which the first Hall element H1 and the second Hall element H2 are connected in series to each other between the power supply voltage VDD and the ground voltage GND, it is possible to input the signals in the appropriate voltage range to the first amplification circuit 31 and the second amplification circuit 32.

For example, the Hall signals 401 and 402 that change up to approximately ±0.24 V while 2.475 V (VDD×3/4) is set as the center are input to the base electrodes of the transistors Q11 and Q12 forming a differential input stage of the first amplification circuit 31 as described above. Thus, the first amplification circuit 31 can perform the appropriate amplification operation. For example, as illustrated in FIG. 5A, between the power supply voltage VDD (3.3 V) and the ground voltage (0 V), it is possible to generate the amplification signals 401A and 402A obtained by linearly amplifying the Hall signals 401 and 402 of the first Hall element H1.

Similarly, as described above, the Hall signals 411 and 412 that change by up to approximately ±0.24 V while 0.825 V (VDD×1/4) is set as the center are input to the base electrodes of the transistors Q21 and Q22 forming a differential input stage of the second amplification circuit 32. Thus, the second amplification circuit 32 can perform the appropriate amplification operation. For example, as illustrated in FIG. 5B, between the power supply voltage VDD (3.3 V) and the ground voltage (0 V), it is possible to generate the amplification signals 411A and 412A obtained by linearly amplifying the Hall signals 411 and 412 of the second Hall element H2.

In addition, in this manner, since a voltage that is suppressed to be low as much as possible in a range where the transistors are released is applied to the base electrodes of the transistors Q11 and Q12, and Q21 and Q22 of the differential input circuits 313 and 323 of the first amplification circuit 31 and the second amplification circuit 32, a current having an appropriate magnitude can flow in the differential input circuits 313 and 323. Thus, it is possible to suppress the power consumption of the first amplification circuit 31 and the second amplification circuit 32.

In addition, when the configuration in which the first Hall element H1 is connected in series to the second Hall element H2 is adopted, it is possible to suppress the voltage fluctuation of the Hall signals 401, 402, 411, and 412 due to the temperature change. That is, the resistance values (absolute values) of the respective internal resistances r1 to r4 of the two Hall elements H1 and H2 change due to the temperature change, but the resistance values of the internal resistances r1 to r4 of the two Hall elements H1 and H2 similarly change in response to the temperature, so that the resistance ratios of the internal resistances r1 to r4 of the first Hall element H1 and the second Hall element H2 do not change. Therefore, the Hall signals 401, 402, 411, and 412 generated by dividing the voltage between the power supply voltage VDD and the ground voltage GND on the basis of the resistance ratios of the internal resistances r1 to r4 hardly fluctuate in response to the temperature. Thus, it is possible to generate the Hall signals having the high stability to the temperature.

In addition, when the configuration in which the first Hall element H1 is connected in series to the second Hall element H2 is adopted, it is possible to decrease the input voltages and the input currents to be applied to the individual Hall elements H1 and H2. For example, the same power supply as the operation power supply (for example, 3.3 V) of the MPU or the like forming the control circuit 5 is supplied to the magnetic detection unit 2, a voltage corresponding to half of the operation power supply of the MPU or the like is applied to each of the Hall elements H1 and H2. For this reason, it is possible to adopt even the Hall elements to which the input voltage at 3.3 V cannot be applied due to a specification, as the two Hall elements H1 and H2 of the angle detection device 1.

In addition, since the bridge circuit formed by the internal resistances r1 to r4 of the first Hall element H1 and the bridge circuit formed by the internal resistances r1 to r4 of the second Hall element H2 are connected in series between the power supply voltage VDD and the ground voltage GND, the input current to each of the Hall elements H1 and H2 can be decreased. It is noted that when it is desired that the input current is to be further restricted, a resistance may also be additionally connected in series on an input side of the two Hall elements H1 and H2.

In addition, when the two Hall elements H1 and H2 are connected in series such that the voltage to be applied to each of the Hall elements H1 and H2 is decreased to be lower than the voltage between the power source and the ground, it is possible to use the operation power supply of the circuit other than the angle detection device 1 as the power supply of the magnetic detection unit 2. Thus, since the power supply circuit does not need to be additionally disposed for the sole purpose of driving the two Hall elements H1 and H2, it is possible to suppress the increase in a circuit scale.

In addition, in accordance with the angle detection device 1 according to the present embodiment, since the commercially available high precision operational amplifier IC does not need to be used, it is possible to suppress costs. For example, when discrete parts are adopted as the circuit elements forming the first amplification circuit 31 and the second amplification circuit 32, it is possible to suppress the costs of the angle detection device 1. It is however noted that with regard to the circuit elements in which highly characteristic pair properties are demanded such as the transistors forming the differential input stage, it is rather preferable to use an IC or the like in which appropriate electronic parts such as, for example, a plurality of transistors having the same performances are housed in one package.

As explained above, in accordance with the angle detection device 1 according to the present embodiment, it is possible to solve the various problems that occur in a case where the Hall elements are adopted, and provide the inexpensive and highly precise magnetic system angle sensor of the absolute type.

### Second Embodiment

### <Motor Unit>

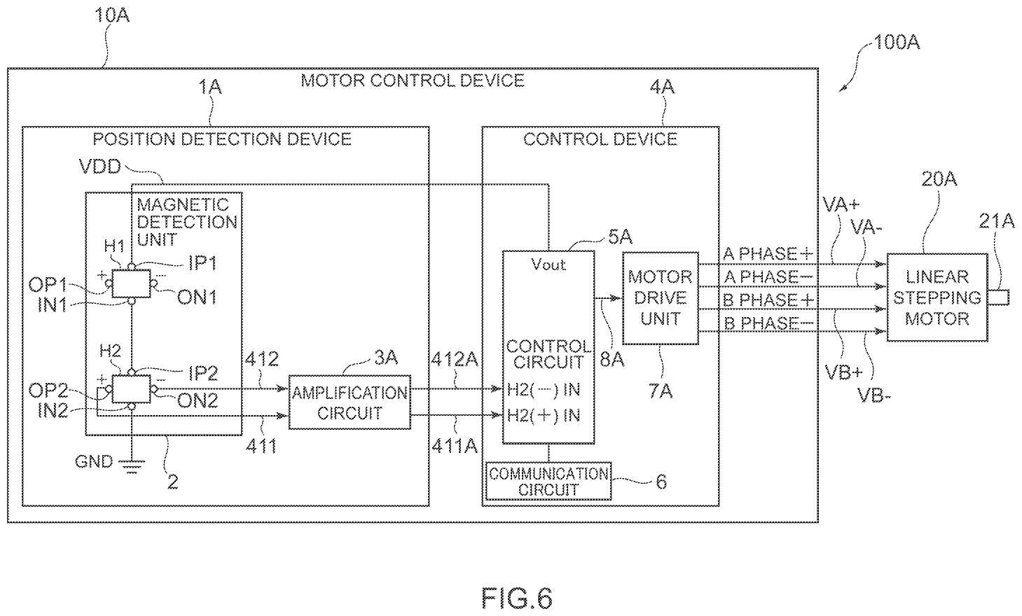

FIG. 6 is a diagram illustrating a configuration of a motor unit according to a second embodiment.

As illustrated in FIG. 6, a motor unit 100A has a motor 20A and a motor control device 10A.

The motor 20A is, for example, a linear motion type motor. According to the present embodiment, the description will be provided by taking a case as an example where the motor 20A is a two-phase linear stepping motor having two phases of a phase A and a phase B.

The motor control device 10A is configured to supply drive power to the motor 20A and drive the motor 20A. Specifically, the motor control device 10A has a position detection device 1A and a control device 4A. The position detection device 1A is an device that generates and outputs a signal corresponding to a position of an output shaft 21A in accordance with a movement of the output shaft of the motor 20A. The control device 4A applies the drive signal to the motor 20A and rotates a rotor of the motor 20A on the basis of a signal output from the position detection device 1A in accordance with the movement of the output shaft 21A of the motor 20A. The output shaft 21A linearly moves by the rotation of the rotor.

### <Control Device>

The control device 4A has a motor drive unit 7A that drives the motor 20A, a control circuit 5A that controls the drive of the motor 20A, and the communication circuit 6 configured to communicate with the external device (not illustrated). It is noted that components of the control device 4A illustrated in FIG. 1 are a part of the entirety, and the control device 4A may also have other components in addition to the components illustrated in FIG. 6.

The motor drive unit 7A generates the drive signals (drive voltages) VA+, VA−, VB+, and VB− for driving the coils of the respective phases forming the motor 20A on the basis of a drive control signal 8A output from the control circuit 5A, and supplies the drive signals to the respective phases of the motor 20A.

The control circuit 5A is formed by a program processing device such as, for example, an MCU or a DSP. It is noted that the entirety of the control circuit 5A may also be packaged as one integrated circuit device, or the entirety or a part of the control circuit 5A may also be packaged together with other devices to form one integrated circuit device.

The control circuit 5A generates the drive control signal 8A on the basis of a command position signal (signal indicating a target position of the output shaft 21A) which is set from the external device (user) via the communication circuit 6 or the like and signals 411A and 412A described below which are output from the position detection device 1A and indicate the position of the output shaft 21A of the motor 20A, and supplies the generated drive control signal 8A to the motor drive unit 7A. That is, the control circuit 5A generates the drive control signal 8A for driving the motor 20A while a feedback is applied by the comparison between the target position and an actual measurement value of the position of the output shaft 21A, and supplies the drive control signal 8A to the motor drive unit 7A, so that the rotation control of the motor 20A is performed.

In addition, the control circuit 5A has a function of outputting a fixed voltage that can be used as a power supply voltage of a peripheral circuit. The control circuit 5A is supplied with the power supply voltage at 3.3 V, for example, to operate, and also outputs the fixed voltage at 3.3 V, for example, while the input power supply voltage is as the power supply voltage VDD of the position detection device 1A.

### <Position Detection Device>

The position detection device 1A has a configuration in which a plurality of Hall elements serving as magnetic detection elements are connected in series to each other on an input side of each of the Hall elements. The position detection device 1A is a sensor of the absolute type which can detect an absolute position of the output shaft 21A of the motor 20A on the basis of a detection signal of the Hall element.

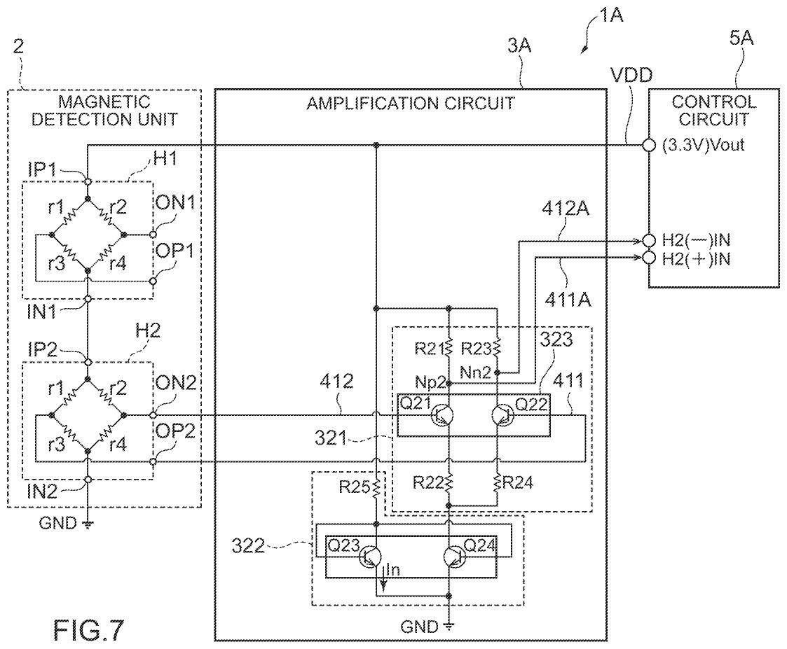

FIG. 7 is a diagram illustrating a circuit configuration of the position detection device 1A.

As illustrated in FIG. 7, the position detection device 1A has the magnetic detection unit 2 and an amplification circuit 3A.

In the magnetic detection unit 2, the second Hall element H2 out of the two Hall elements H1 and H2 is used for detecting the position of the output shaft 21A of the motor 20A. On the other hand, the first Hall element H1 is not used for detecting the position of the output shaft 21A, but is disposed as a dummy element for compensating the characteristics of the second Hall element H2.

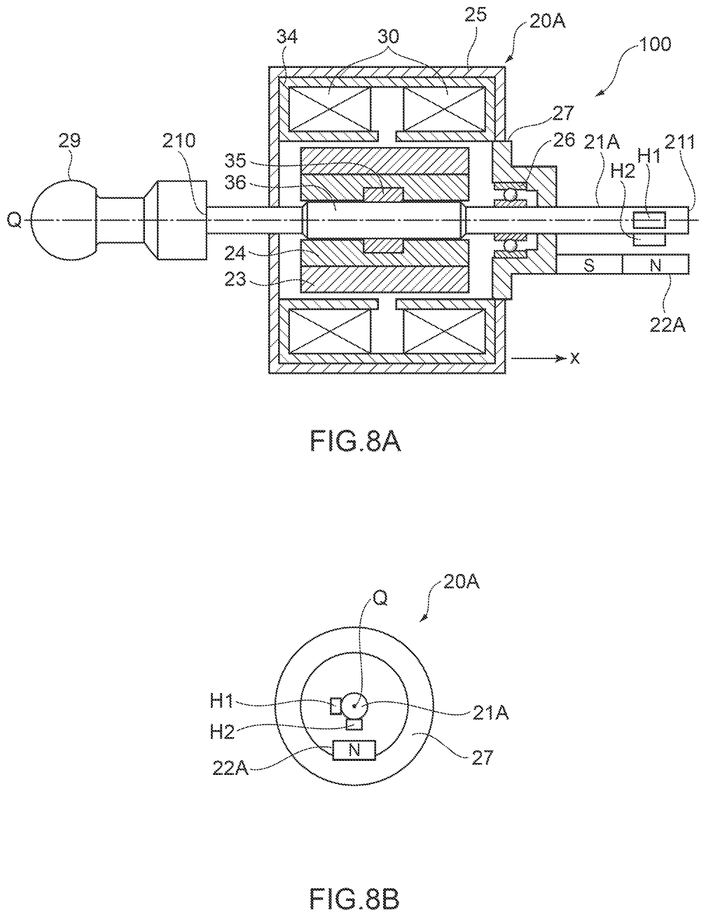

FIG. 8A and FIG. 8B are views illustrating arrangement examples of the two Hall elements H1 and H2.

FIG. 8A illustrates the arrangement example of the two Hall elements H1 and H2 viewed from a direction perpendicular to an axis line Q of the output shaft 21A of the motor 20A in the motor unit 100A. FIG. 8B illustrates the arrangement example of the two Hall elements H1 and H2 viewed from a direction of the axis line Q of the output shaft 21A of the motor 20A in the motor unit 100A.

As illustrated in FIGS. 8A and 8B, in the motor unit 100A, the motor 20A has a stator unit, a rotor unit, the output shaft 21A, a bearing 26, a cover 27, a case 25, and the like as the components of the linear stepping motor. It is noted that FIGS. 8A and 8B illustrate only a part of components forming the motor 20A.

In the motor 20A, the stator unit and the rotor unit are housed in the case 25. The stator unit includes a coil 30 and a stator yoke 34. The rotor unit includes a rotor magnet 23 and a rotor part 24. A female screw portion 35 is embedded in the rotor part 24. In addition, a male screw portion 36 is screwed into an inside of the female screw portion 35. The output shaft 21A is arranged in a penetrating state through the case 25. A head 29 set as a drive target is fixed on a side of a one end portion 210 of the output shaft 21A.

When the female screw portion 35 formed in the rotor part 24 is engaged with the male screw portion 36 in the case 25, the rotor part 24 is joined to the output shaft 21A. When the rotor unit rotates, the female screw portion 35 embedded in the rotor part 24 also rotates. When the female screw portion 35 rotates, the male screw portion 36 engaged with the female screw portion 35 moves in the axis direction due to a principle similar to a feeding mechanism using a ball screw, and as a result, the output shaft 21A moves in the axis line Q. That is, in the motor 20A, the rotational motion of the rotor unit is converted into the linear motion of the output shaft 21A.

As illustrated in FIG. 8A, the two Hall elements H1 and H2 are fixed on a side of another end portion 211 of the output shaft 21A. Thus, when the output shaft 21A moves in the direction of the axis line Q, the two Hall elements H1 and H2 also move in the direction of the axis line Q.

A sensor magnet (magnet) 22A is disposed in the vicinity of the two Hall elements H1 and H2. The sensor magnet 22A is, for example, a bipolar permanent magnet having a rectangular plate-like shape.

The sensor magnet 22A is fixed to a position facing the output shaft 21A. Specifically, the sensor magnet 22A is arranged in a position facing the second Hall element H2 in a direction perpendicular to the axis line Q of the output shaft 21A. For example, as illustrated in FIG. 8A and FIG. 8B, the sensor magnet 22A is arranged so as to face the second Hall element H2 on the cover 27 that houses the bearing 26 for holding the end portion 211 side of the output shaft 21A. Thus, the detection amount of a magnetic flux of the sensor magnet 22A by the second Hall element H2 changes when the output shaft 21A moves in the direction of the axis line Q.

It is noted that it is sufficient when the second Hall element H2 and the sensor magnet 22A are disposed in positions where the second Hall element H2 can precisely detect a change of the magnetic flux of the sensor magnet 22A when the output shaft 21A moves by the rotation of the motor 20A, and the installment positions of the second Hall element H2 and the sensor magnet 22A are not limited to the examples illustrated in FIGS. 8A and 8B.

The second Hall element H2 detects the magnetic flux of the sensor magnet 22A, and outputs analog signals (hereinafter, also referred to as “Hall signals”.) in which a voltage changes in accordance with the change of the magnetic flux as the output signal.

As described above, the first Hall element H1 is a dummy element configured to compensate the characteristics of the second Hall element H2. The first Hall element H1 is preferably arranged in the vicinity of the second Hall element H2. That is, the first Hall element H1 is preferably arranged in a position under the same temperature environment as the second Hall element H2. For example, as illustrated in FIGS. 8A and 8B, for example, the first Hall element H1 and the second Hall element H2 are arranged such that a phase in an outer circumferential direction of the output shaft 21A is shifted by 90 degrees (90 degrees or smaller) on an outer circumferential surface of the output shaft 21A.

It is noted that a circuit substrate or the like on which the amplification circuit 3A and the like to be connected to the two Hall elements H1 and H2 are formed may also be arranged within the case 25 of the motor 20A illustrated in FIGS. 8A and 8B or may also be arranged outside the case 25.

### (2) Amplification Circuit

As illustrated in FIG. 7, the amplification circuit 3A is a functional unit that amplifies and outputs each of the Hall signals output from the second Hall element H2.

The amplification circuit 3A is a circuit that amplifies each of the Hall signals 411 and 412 of the second Hall element H2. Specifically, the amplification circuit 3A has the constant current source circuit 322 and the differential amplification circuit 321.

The constant current source circuit 322 is a circuit that generates and supplies a constant current to the differential amplification circuit 321. The constant current source circuit 322 includes, for example, the N type transistors Q23 and Q24 and the resistance R25.

For example, the N type transistors Q23 and Q24 are NPN type bipolar transistors. The transistor Q23 and the transistor Q24 form a current mirror circuit.

In the constant current source circuit 322, the base electrode and the collector electrode of the transistor Q23 are commonly connected, and the emitter electrode of the transistor Q23 is supplied with the ground voltage GND.

The one end of the resistance R25 is connected to the base electrode and the collector electrode of the transistor Q23, and the other end of the resistance R25 is supplied with the power supply voltage VDD. The emitter electrode of the transistor Q24 is supplied with the ground voltage GND. The base electrode of the transistor Q24 is connected to the one end of the resistance R25 together with the base electrode and the collector electrode of the transistor Q23, and the collector electrode of the transistor Q24 is connected to a node to which the resistance R22 and the resistance R24 forming the differential input circuit 323 which will be described below are mutually connected.

In accordance with the constant current source circuit 322 having the above-described configuration, when the base-emitter voltage of the transistor Q23 is set as VBE23, the current In=(VDD−VBE23)/R25 is output from the transistor Q23, and the current that has copied the current In is supplied from the transistor Q24 to the differential amplification circuit 321.

The differential amplification circuit 321 is a circuit that amplifies and outputs a difference between the Hall signal 411 output from the second positive side output terminal OP2 of the second Hall element H2 and the Hall signal 412 output from the second negative side output terminal ON2 of the second Hall element H2.

The differential amplification circuit 321 includes the differential input circuit 323 and the resistances R21 to R24. The differential input circuit 323 includes, for example, an N type (second conductivity type) transistor pair. For example, the differential input circuit 323 has the NPN junction bipolar transistors Q21 and Q22 as the transistor pair formed such that the characteristics are equal to each other.

The base electrode of the transistor Q21 is connected to the second negative side output terminal ON2 of the second Hall element H2, and the base electrode of the transistor Q22 is connected to the second positive side output terminal OP2 of the second Hall element H2.

The one end of the resistance R21 is connected to the collector electrode of the transistor Q21, and the other end of the resistance R21 is supplied with the power supply voltage VDD. The one end of the resistance R23 is connected to the collector electrode of the transistor Q22, and the other end of the resistance R23 is supplied with the power supply voltage VDD. The one end of the resistance R22 is connected to the emitter electrode of the transistor Q21. The one end of the resistance R24 is connected to the emitter electrode of the transistor Q22. The other end of the resistance R22 is connected to the other end of the resistance R24 and the collector electrode of the transistor Q24.

In accordance with the differential amplification circuit 321 having the above-described configuration, the amplification signal 411A having the positive polarity which is obtained by amplifying the difference between the Hall signal 411 and the Hall signal 412 is output from the node Np2 to which the one end of the resistance R21 and the collector electrode of the transistor Q21 are connected. In addition, the amplification signal 412A having the negative polarity which is obtained by amplifying the difference between the Hall signal 411 and the Hall signal 412 is output from the node Nn2 to which the one end of the resistance R23 and the collector electrode of the transistor Q22 are connected.

In this manner, the Hall signals 411 and 412 of the second Hall element H2 are amplified by the amplification circuit 3A and input as the amplification signals 411A and 412A to the control circuit 5A.

The control circuit 5A calculates an actual measurement value of the position of the output shaft 21A of the motor 20A on the basis of the input amplification signals 411A and 412A. As described above, the amplification signals 411A and 412A (Hall signals 411 and 412) are signals obtained by converting the magnitude of the magnetic flux that changes in accordance with a positional relationship between the sensor magnet 22A and the second Hall element H2 into a voltage. Therefore, the control circuit 5A can calculate the absolute position of the output shaft 21A of the motor 20A from the magnitudes of the voltages of the amplification signals 411A and 412A. For example, a table, a relational expression, or the like representing a correspondence relationship between voltage values of the amplification signals 411A and 412A and the position information of the output shaft 21A may be previously stored in the storage unit in the control circuit 5A, and the control circuit 5A may calculate the absolute position of the output shaft 21A of the motor 20A on the basis of the table, the relational expression, or the like stored in the storage unit and the amplification signals 411A and 412A.

### <Motor Control Method>

Thereafter, a control method of the motor 20A in the motor unit 100A according to the second embodiment will be described.

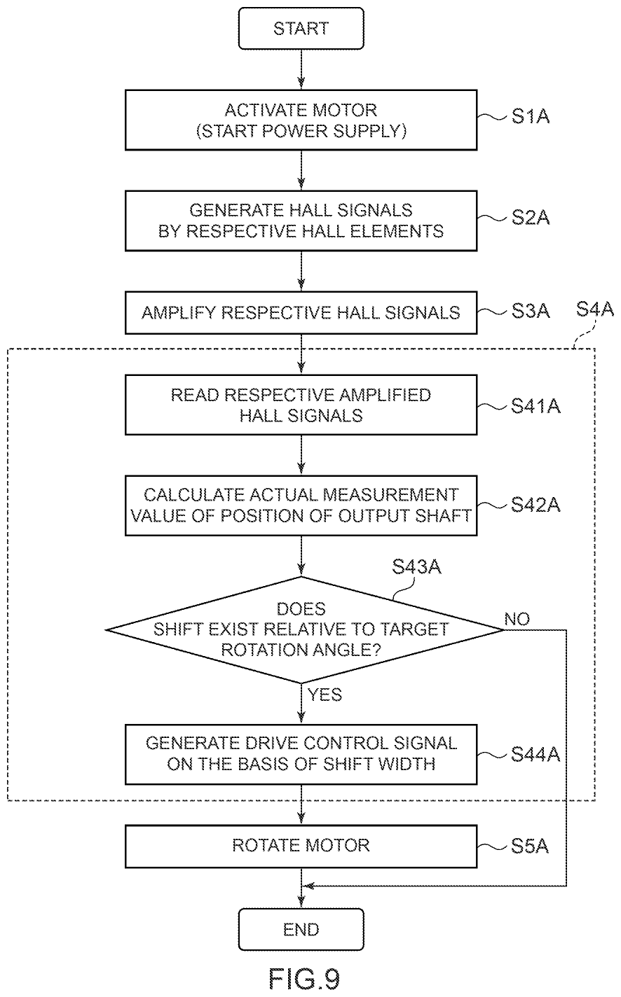

FIG. 9 is a flowchart illustrating a flow of the motor control method in the motor unit 100A according to the second embodiment.

First, when the motor unit 100A is supplied with the power supply voltage, the motor unit 100A is activated (step S1A). Thereafter, the second Hall element H2 disposed in the output shaft 21A of the motor 20A detects the magnetic flux of the sensor magnet 22A, and generates the Hall signals 411 and 412 in accordance with the detected magnetic flux (step S2A).

Thereafter, the amplification circuit 3A of the position detection device 1A respectively amplifies the Hall signals 411 and 412 output from the second Hall element H2 and generates the amplification signals 411A and 412A (step S3A).

Thereafter, the control device 4A executes processing for generating the drive signals for driving the motor 20A on the basis of the amplification signals 411A and 412A output from the position detection device 1A (step S4A).

Specifically, first, the control circuit 5A of the control device 4A reads the amplification signals 411A and 412A obtained by amplifying the Hall signals of the second Hall element H2 (step S41A). For example, the control circuit 5A converts the amplification signals 411A and 412A corresponding to the analog signals by an analog/digital conversion circuit (not illustrated) disposed inside the control circuit 5A into digital signals, and stores the digital signals in the storage unit (not illustrated) disposed inside the control circuit 5A.

Thereafter, the control circuit 5A calculates an actual measurement value of the position of the output shaft 21A of the motor 20A on the basis of the read amplification signals 411A and 412A (step S42A). At this time, when the second Hall element H2 fixed to the output shaft 21A and the Hall signals 411 and 412 (amplification signals 411A and 412A) of the second Hall element H2 in which the voltage changes in accordance with the positional relationship with the sensor magnet 22A are used, it is possible to calculate the absolute position of the output shaft 21A.

Thereafter, the control circuit 5A compares the target position set from the external device via the communication circuit 6 or the like with the actual measurement value of the position of the output shaft 21A of the motor 20A which is calculated in step S42A (step S43A). In step S43A, in a case where the target position and the actually measured position has a shift, the control circuit 5A generates the drive control signal 8A such that the shift width is reduced (step S44A).

Thereafter, the motor drive unit 7A generates the drive signals (drive voltages) VA+, VA−, VB+, and VB− on the basis of the drive control signal 8A generated in step S44A, and supplies the drive signals to the respective phases of the motor 20A to rotate the motor 20A and move the output shaft 21A (step S5A). Thus, the motor 20A is controlled such that the output shaft 21A reaches the target position.

### <Effects of Position Detection Device>

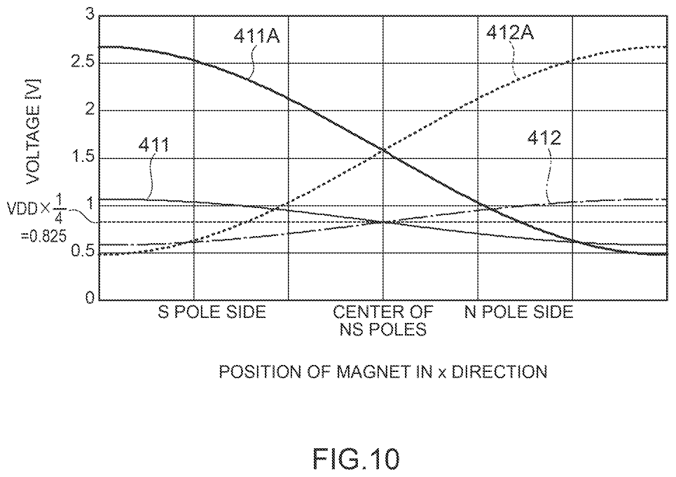

FIG. 10 is a diagram illustrating a simulation result of input signals and output signals of the amplification circuit 3A in the position detection device according to the second embodiment. In this simulation, the power supply voltage VDD=3.3 V and the ground voltage GND=0 V are set.

In FIG. 10, the horizontal axis represents a position of the sensor magnet (magnet) 22A in an x direction in FIG. 8A, and the vertical axis represents a voltage [V]. In addition, FIG. 10 illustrates the Hall signals 411 and 412 of the second Hall element H2 as the input signals of the amplification circuit 3A, and the amplification signals 411A and 412A as the output signals of the amplification circuit 3A when the output shaft 21A of the motor 20A is moved from an S pole side to an N pole side of the sensor magnet 22A.

In the position detection device 1A according to the second embodiment, as described above, the first Hall element H1 and the second Hall element H2 are connected in series to each other on the respective input sides between the power supply voltage VDD and the ground voltage GND in the magnetic detection unit 2.

For this reason, the reference voltage of the Hall signals of the second Hall element H2 is a voltage obtained by dividing the voltage between the power supply voltage VDD and the ground voltage GND on the basis of resistance ratios of the internal resistances r1 to r4 of each of the Hall elements H1 and H2. That is, when each of the internal resistances r1 to r4 of the second Hall element H2 is in the equilibrium state, the reference voltage of the Hall signals of the first Hall element H1 is set as “VDD×3/4”, and the reference voltage of the second Hall element H2 is set as “VDD×1/4”.

For example, as illustrated in FIG. 10, when the power supply voltage VDD=3.3 V and the ground voltage GND=0 V are set, the reference voltage of the second Hall element H2 is set as 0.825 V (=3.3×1/4), and the Hall signals 411 and 412 of the second Hall element H2 have waveforms that change by up to approximately ±0.24 V while 0.825 V is set as the center.

On the other hand, since the amplification circuit 3A to which the Hall signals 411 and 412 of the second Hall element H2 are input has the differential input circuit 323 formed by the transistors Q21 and Q22 of the NPN type, unless the signal in the appropriate voltage range is input, the amplification circuit 3A does not perform the appropriate amplification operation. For example, in order that the transistors Q21 and Q22 appropriately operate, when the saturation voltage of the PN junction portion of the transistors Q21 and Q22 is set as VBE20 (≈0.6 V), a voltage equal to or higher than “VBE20 (≈0.6 V)” needs to be input to the base electrodes of the transistors Q21 and Q22. On the other hand, in a case where a high voltage close to the power supply voltage VDD is input to the base electrodes of the transistors Q21 and Q22, the output voltage of the amplification circuit 3A saturates.

In this manner, the amplification circuit 3A that amplifies the output signals from the Hall element has a limitation on the input voltage range, but since the position detection device 1A according to the second embodiment adopts a configuration in which the first Hall element H1 and the second Hall element H2 are connected in series to each other between the power supply voltage VDD and the ground voltage GND, it is possible to input the signals in the appropriate voltage range to the amplification circuit 3A.

For example, as described above, the Hall signals 411 and 412 that change by up to approximately ±0.24 V while 0.825 V (VDD×1/4) is set as the center is input to the base electrodes of the transistors Q21 and Q22 forming the differential input circuit 323 of the amplification circuit 3A. Thus, the amplification circuit 3A can perform the appropriate amplification operation. For example, as illustrated in FIG. 10, it is possible to generate the amplification signals 411A and 412A obtained by linearly amplifying the Hall signals 411 and 412 of the second Hall element H2 between the power supply voltage VDD (3.3 V) and the ground voltage (0 V).

In addition, in this manner, since a voltage that is suppressed to be low as much as possible in a range where the transistors are released is applied to the base electrodes of the transistors Q21 and Q22 of the differential input circuit 323 of the amplification circuit 3A, a current having an appropriate magnitude can flow in the differential input circuit 323. Thus, it is possible to suppress the power consumption of the amplification circuit 3A.

In addition, when the dummy Hall element H1 is connected in series instead of using the second Hall element H2 used for the magnetic detection alone, it is possible to suppress the voltage fluctuation of the Hall signals 411 and 412 of the second Hall element H2 caused by the change of the temperature. That is, the absolute values (resistance values) of the respective internal resistances r1 to r4 of the two Hall elements H1 and H2 connected in series change in response to the temperature, but since the tendency of the change is similar among the respective internal resistances r1 to r4, the resistance ratios of the internal resistances r1 to r4 of the first Hall element H1 and the second Hall element H2 do not change. Therefore, the Hall signals 411 and 412 generated by dividing the voltage between the power supply voltage VDD and the ground voltage GND on the basis of the resistance ratios of the internal resistances r1 to r4 of the first Hall element H1 and the second Hall element H2 hardly fluctuate in response to the temperature. Thus, it is possible to generate the Hall signals having the high stability to the temperature.

In addition, when the configuration in which the first Hall element H1 is connected in series to the second Hall element H2 is adopted, it is possible to decrease the input voltages and the input currents to be applied to the individual Hall elements H1 and H2.

For example, in a case where the same power supply as the operation power supply (for example, 3.3 V) such as the MPU forming the control circuit 5A is supplied to the magnetic detection unit 2, a voltage corresponding to half of the operation power supply such as the MPU is applied to each of the Hall elements H1 and H2. For this reason, even when the Hall element to which the input voltage at 3.3 V cannot be applied due to a specification can be adopted as the two Hall elements H1 and H2 of the position detection device 1A. In addition, since the bridge circuit formed by the internal resistances r1 to r4 of the first Hall element H1 and the bridge circuit formed by the internal resistances r1 to r4 of the second Hall element H2 are connected in series between the power supply voltage VDD and the ground voltage GND, the input current to each of the Hall elements H1 and H2 can be decreased.

It is noted that when it is desired that the input current is to be further restricted, a resistance may also be additionally connected in series on an input side of the two Hall elements H1 and H2.

In addition, when the two Hall elements H1 and H2 are connected in series such that the voltage to be applied to each of the Hall elements H1 and H2 is decreased to be lower than the voltage between the power source and the ground, it is possible to use the operation power supply of the circuit other than the position detection device 1A as the power supply of the magnetic detection unit 2 as described above. Thus, since the power supply circuit does not need to be additionally disposed for the sole purpose of driving the two Hall elements H1 and H2, it is possible to suppress the increase in the circuit scale.

In addition, in accordance with the position detection device 1A according to the second embodiment, since the commercially available high precision operational amplifier IC does not need to be used, it is possible to suppress the costs. For example, when a discrete part is adopted as the circuit element forming the amplification circuit 3A, it is possible to suppress the costs of the position detection device 1A. It is however noted that with regard to the circuit elements in which highly characteristic pair properties are demanded such as the transistors forming the differential input stage, it is rather preferable to use an IC or the like in which appropriate electronic parts such as, for example, a plurality of transistors having the same performances are housed in one package.

As explained above, in accordance with the position detection device 1A according to the second embodiment, it is possible to solve the various problems that occur in a case where the Hall elements are adopted, and provide a new, inexpensive, highly precise magnetic system position detection sensor of the absolute type.

### Extension of Embodiments

The invention made by the present inventors has been specifically described above by way of the embodiments, but the present invention is not limited to the embodiments, and various alterations can be made of course within a range without departing from the gist of the invention.

For example, in the motor unit 100 according to the first embodiment, the installment positions of the sensor magnet 22 and the two Hall elements H1 and H2 are not limited to the positions illustrated in FIG. 3A and FIG. 3B. That is, it is sufficient when the sensor magnet 22 is installed in a position where the magnetic flux of the sensor magnet 22 changes by the rotation of the rotor of the motor 20, and it is also sufficient when the two Hall elements H1 and H2 are installed in positions where the change of the magnetic flux of the sensor magnet 22 can be detected.

In addition, according to the first embodiment, the case has been exemplified where the motor 20 is a two-phase stepping motor, but may also be a three-phase or five-phase stepping motor, for example, and may also be a motor of another type (such as, for example, a brushless motor).

According to the second embodiment, the case has been exemplified where the magnetic flux of the sensor magnet 22A is detected by the second Hall element H2 out of the two Hall elements H1 and H2, but is not limited to this, and the magnetic flux of the sensor magnet 22A may also be detected by the first Hall element H1.

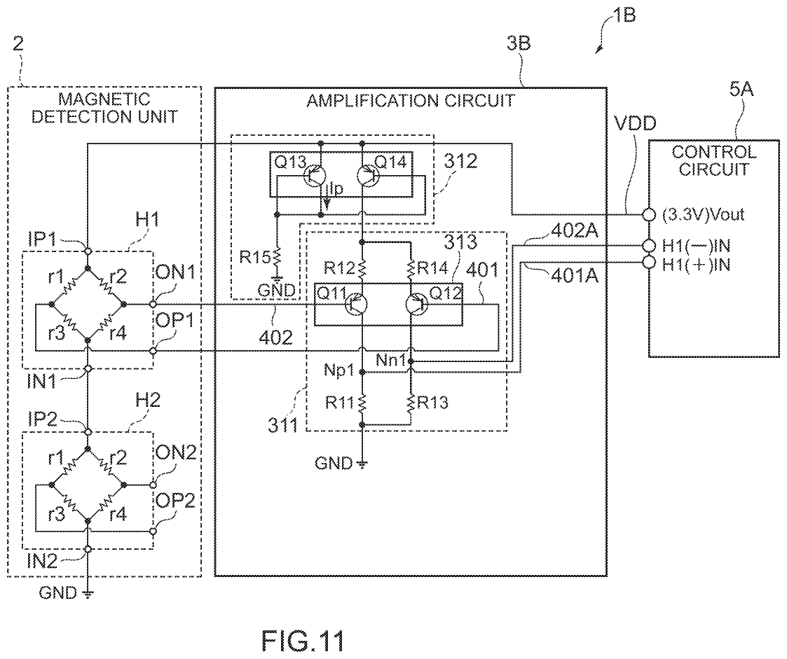

For example, in FIGS. 8A and 8B, the positions of the first Hall element H1 and the second Hall element H2 on the output shaft 21A are swapped, and as illustrated in FIG. 11, an amplification circuit 3B that amplifies the Hall signal output from the first positive side output terminal OP1 of the first Hall element H1 and the Hall signal output from the first negative side output terminal ON1 of the first Hall element H1 is disposed. In this case, as illustrated in FIG. 11, it is preferable to form the amplification circuit 3B by using a transistor having an opposite polarity to the amplification circuit 3A described above, that is, a P type transistor.

For example, in the amplification circuit 3B, the differential input circuit 313 of the differential amplification circuit 311 which receives the Hall signals 401 and 402 having the different polarities which are output from the first Hall element H1 is preferably formed by the pair of the P type transistors Q11 and Q12. Similarly, the constant current source circuit 312 is preferably formed by using the pair of the P type transistors Q13 and Q14.

In addition, according to the above-described embodiments, a case where the bipolar transistors are adopted as the transistors forming the amplification circuits 31, 32, 3A, and 3B has been exemplified, but transistors of other types such as a MOS (Metal-Oxide-Semiconductor) transistor can also be adopted.

In addition, according to the above-described embodiments, the amplification circuits 31, 32, 3A, and 3B are not limited to the above-described circuit configuration. A circuit configuration may be adopted in which the amplification circuits 31, 32, 3A, and 3B can linearly amplify the signals output from the plurality of Hall elements connected in series.

In addition, according to the above-described embodiments, the case has been exemplified where the two Hall elements H1 and H2 are connected in series, but three or more Hall elements may be connected in series when necessary.

In addition, in the motor unit 100A according to the second embodiment, the installment positions of the sensor magnet 22A and the two Hall elements H1 and H2 are not limited to the positions illustrated in FIG. 8A and FIG. 8B. That is, one of the second Hall element H2 and the sensor magnet 22A may be fixed to the output shaft 21A, and the other one of the second Hall element H2 and the sensor magnet 22A may be fixed to a position that is not moved in accordance with the movement of the output shaft 21A. For example, in FIGS. 8A and 8B, the two Hall elements H1 and H2 and the sensor magnet 22A may also be swapped to be arranged. That is, the two Hall elements H1 and H2 may also be arranged on the cover 27, and the sensor magnet 22A may also be fixed on the side of the end portion 211 of the output shaft 21A.

In addition, according to the second embodiment, the case has been exemplified where the motor 20A is the two-phase linear stepping motor, but any linear motion type motor can be applied to various motors. For example, the motor 20A may also be a three-phase or five-phase linear stepping motor, or may also be a motor of other types (such as, for example, a brushless motor).

In addition, according to the second embodiment, the case has been exemplified where the position detection device 1A is applied to the motor unit to detect the absolute position of the output shaft of the linear stepping motor, but the application to be applied is not limited to the motor. For example, the position detection device 1A can be applied to various applications in which the shaft moves in the linear motion direction.

In addition, the above-described flowchart illustrates an example for describing the operation, and is not limited to this. That is, steps illustrated in the respective diagrams of the flowchart are an example, and are not limited to this flow. For example, an order of a part of processes may also be changed, another process may also be inserted between the processes, and a part of processes may also be performed in parallel.

### LIST OF REFERENCE SYMBOLS

1 angle detection device
1A, 1B position detection device
2 magnetic detection unit
3 amplification unit
3A, 3B amplification circuit
4, 4A control device
5, 5A control circuit
6 communication circuit
7, 7A motor drive unit
8, 8A drive control signal
10, 10A motor control device
20, 20A motor
21, 21A output shaft
22, 22A sensor magnet (magnet)
31 first amplification circuit
32 second amplification circuit
100, 100A motor unit
311, 321 differential amplification circuit
312, 322 constant current source circuit
313, 323 differential input circuit
401, 402, 411, 412 Hall signal
401A, 402A, 411A, 412A amplification signal
GND ground voltage
H1 first Hall element
H2 second Hall element
IN1 first negative side input terminal
IN2 second negative side input terminal
IP1 first positive side input terminal
IP2 second positive side input terminal
ON1 first negative side output terminal
ON2 second negative side output terminal
OP1 first positive side output terminal
OP2 second positive side output terminal
P axis line
Q11 to Q14, Q21 to Q24 transistor
R rotation direction
r1 to r4 internal resistance
R11 to R15, R21 to R25 resistance
VDD power supply voltage

1. (canceled)

2. (canceled)

3. An angle detection device comprising:
a magnetic detection unit including a plurality of Hall elements being connected in series to each other on an input side of each of the Hall elements; and
a plurality of amplification circuits respectively disposed for the Hall elements and configured to amplify output signals of the corresponding Hall elements,
wherein the plurality of Hall elements includes
a first Hall element having a first positive side input terminal, a first negative side input terminal, a first positive side output terminal, and a first negative side output terminal, and a second Hall element having a second positive side input terminal, a second negative side input terminal, a second positive side output terminal, and a second negative side output terminal,
a power supply voltage is applied to the first positive side input terminal of the first Hall element,
the first negative side input terminal of the first Hall element is connected to the second positive side input terminal of the second Hall element, and
a ground voltage is applied to the second negative side input terminal of the second Hall element.

4. The angle detection device according to claim 3, wherein
the plurality of amplification circuits include a first amplification circuit that amplifies a difference between a voltage of the first positive side output terminal and a voltage of the first negative side output terminal in the first Hall element, and a second amplification circuit that amplifies a difference between a voltage of the second positive side output terminal and a voltage of the second negative side output terminal in the second Hall element,
the first amplification circuit has a differential input circuit including a P type transistor pair, and
the second amplification circuit has a differential input circuit including an N type transistor pair.

5. (canceled)

6. A motor unit comprising:
a motor control device;
a motor; and
a magnet,
wherein the motor control device includes
the angle detection device according to claim 3;
a control device that generates a drive control signal for controlling drive of a motor on the basis of signals respectively amplified by the plurality of amplification circuits,
wherein the motor is controlled on the basis of the drive control signal generated by the control device,
wherein the magnet is disposed on an output shaft of the motor,
wherein the plurality of Hall elements is arranged while being separated from each other along a direction in which the magnet rotates.

7. The motor unit according to claim 6, wherein
the Hall elements include two Hall elements, and the two Hall elements are arranged such that phases are mutually shifted by 90 degrees.

8. A position detection device comprising:
a magnetic detection unit including a plurality of Hall elements being connected in series to each other on an input side of each of the Hall elements; and
an amplification circuit that amplifies output signals of one Hall element of the plurality of Hall elements,
wherein the plurality of Hall elements includes
a first Hall element having a first positive side input terminal, a first negative side input terminal, a first positive side output terminal, and a first negative side output terminal, and a second Hall element having a second positive side input terminal, a second negative side input terminal, a second positive side output terminal, and a second negative side output terminal,
a power supply voltage is applied to the first positive side input terminal of the first Hall element,
the first negative side input terminal of the first Hall element is connected to the second positive side input terminal of the second Hall element, and
a ground voltage is applied to the second negative side input terminal of the second Hall element.

9. The position detection device according to claim 8, wherein
the amplification circuit amplifies a difference between a voltage of the second positive side output terminal and a voltage of the second negative side output terminal in the second Hall element, and
the amplification circuit has a differential input circuit including an N type transistor pair.

10. (canceled)

11. A motor unit comprising:
a motor control device;
a motor; and
a magnet,
wherein the motor control device includes
the position detection device according to claim 8; and
a control device that generates a drive control signal for controlling drive of the motor on the basis of the signals amplified by the amplification circuit,
wherein the motor is a linear motion type motor that has an output shaft in which a movement in an axis line direction of the output shaft is controlled on the basis of the drive control signal, and
one of the one Hall element and the magnet is fixed to the output shaft, and the other one of the one Hall element and the magnet is fixed to a position facing the output shaft.

12. The motor unit according to claim 11, wherein
the one Hall element is fixed to the output shaft, and
the magnet is fixed to the position facing the output shaft.

13. (canceled)

14. (canceled)
